(19) United States
(12) Patent Application Publication
(10) Pub. No.: US 2018/0195163 A1
(43) Pub. Date: Jul. 12, 2018

(54) COOLING AND UTILIZATION OPTIMIZATION OF HEAT SENSITIVE BONDED METAL TARGETS

(71) Applicant: Applied Materials, Inc., Santa Clara, CA (US)

(72) Inventors: Helmut GRIMM, Darmstadt (DE); Thomas Werner ZILBAUER, Gauting (DE)

(21) Appl. No.: 15/742,180

(22) PCT Filed: Jul. 24, 2015
(86) PCT No.: PCT/EP2015/067047

§ 371 Date: Jan. 5, 2018

(51) Int. Cl. C23C 14/34; C23C 14/35; C23C 14/16; H01J 37/34

(52) U.S. Cl. CPC C23C 14/3407; C23C 14/35; C23C 14/165; H01J 37/3497; H01J 37/3417; H01J 37/3426; H01J 37/3435; H01J 37/3408

(57) ABSTRACT

A sputtering source is described. The sputtering source includes a backing support having a target receiving surface and a further surface opposing the target receiving surface, and at least one magnet assembly provided adjacent the further surface, wherein the target receiving surface of the backing support has at least one recess, wherein the recess is provided opposite to the magnet assembly.

### TECHNICAL FIELD

Embodiments described herein relate to layer deposition by sputtering from a target. Embodiments described herein particularly relate to a sputtering source having a backing support and a method for operating the sputtering source, and relate to an apparatus for sputter deposition of a substrate.

### BACKGROUND

Techniques for depositing thin layers on a substrate are, in particular, evaporating, chemical vapor deposition (CVD) and sputtering deposition, also known as physical vapor deposition (PVD). For example, sputtering can be used to deposit a thin layer such as a thin layer of a metal. During the sputtering process, the coating material is transported from a sputtering target consisting of the material to be deposited on the substrate by bombarding the surface of the target with ions. During a sputtering process, a target may be electrically biased so that ions generated in a process region may bombard the target surface with sufficient energy to dislodge atoms of target material from the target surface. The sputtered atoms may deposit onto a substrate. The sputtered atoms may react with a gas in the plasma, for example nitrogen or oxygen, to deposit e.g. an oxide, a nitride or an oxinitride of the material onto the substrate: This can be referred to as reactive sputtering.

In a PVD process, the sputter material, i.e. the material to be deposited on the substrate, may be arranged in different ways. For instance, the target may be made from the material to be deposited or may have a backing element on which the material to be deposited is fixed. The target including the material to be deposited may be supported or fixed in a predefined position in a deposition chamber.

There are two general types of sputtering targets, planar sputtering targets and rotary sputtering targets. Both planar and rotary sputtering targets have advantages. Due to the geometry and design of the cathodes, rotary targets might have a higher utilization and an increased operation time as compared to planar ones. Furthermore, rotary sputtering targets may be particularly beneficial in large area substrate processing. However, planar sputtering targets might also be used for large area substrate processing. In this case, multiple tiles of sputtering material might be separately bonded to a single target backing plate.

Coated materials may be used in several applications and in several technical fields. For instance, an application lies in the field of microelectronics, such as generating semiconductor devices or thin film batteries for smaller portable battery powered devices. Also, substrates for displays are often coated by a PVD process. Further applications include insulating panels, organic light emitting diode (OLED) panels, substrates with TFT, color filters or the like.

During sputtering plasma (ions, electrons) may transfer energy of 19-60 kW to the target surface. Accordingly, the target experiences a heat load. In cases where the target is made of a heat sensitive material, e.g., alkali metal or alkaline earth metal, the heat load has to be dissipated in order to avoid melting and/or evaporation of the target material (e.g., lithium has a melting point at 180° C.). In view of the foregoing, the target is usually provided with a backing support for the target layer in which cooling channels are provided.

Accordingly, there is an ongoing need for an optimized thermal conduction between a target and its backing support and a better utilization of the target material.

### SUMMARY

In light of the above, a sputtering source, a method for operating the sputtering source and an apparatus for sputter deposition of a substrate according to independent claims 1, 9 and 14 are provided. Further aspects, advantages, and features of the embodiments of the present disclosure are apparent from the dependent claims, the description and the accompanying drawings.

According to one aspect, a sputtering source is provided. The sputtering source includes a backing support having a target receiving surface and a further surface opposing the target receiving surface, and at least one magnet assembly provided adjacent to the further surface, wherein the target receiving surface of the backing support has at least one recess, wherein the recess is provided opposite to the magnet assembly.

According to another aspect, a method for operating a sputtering source is provided. The method includes providing a magnet assembly, and providing a backing support having a target receiving surface and a further surface opposing the target receiving surface, wherein the target receiving surface of the backing support has at least one recess, wherein the recess is provided opposite to the magnet assembly.

According to another aspect, an apparatus for sputter deposition of a substrate is provided. The apparatus includes a vacuum chamber configured for sputter deposition of a substrate and a sputtering source. The sputtering source includes a backing support having a target receiving surface and a further surface opposing the target receiving surface, and at least one magnet assembly provided adjacent the further surface, wherein the target receiving surface of the backing support has at least one recess, wherein the recess is provided opposite to the magnet assembly.

The disclosure is also directed to an apparatus for carrying out the disclosed methods and including apparatus parts for performing each described method features. These method features may be performed by way of hardware components, a computer programmed by appropriate software, by any combination of the two or in any other manner. Furthermore, the disclosure is also directed to methods describing the apparatus operation. It includes methods for carrying out every function of the apparatus.

### BRIEF DESCRIPTION OF THE DRAWINGS

So that the manner in which the above recited features of embodiments of the disclosure can be understood in detail, a more particular description of the embodiments, briefly summarized above, may be had by reference to embodiments described herein. The accompanying drawings relate to embodiments of the present disclosure and are described in the following:

FIG. 1A shows a cut view of a sputtering source, according to embodiments described herein;

FIG. 1B shows a perspective view of a backing support, according to embodiments described herein;

FIG. 1C shows a cut view of a sputtering source comprising a target material, according to embodiments described herein

FIG. 2A shows a cut view of a sputtering source comprising multiple target tiles, according to embodiments described herein;

FIG. 2B shows a cut view of a sputtering source comprising multiple target tiles, according to embodiments described herein;

FIG. 3 shows a schematic view of a deposition apparatus for sputter deposition of a substrate, according to embodiments described herein; and

FIG. 4 shows a flow chart illustrating a method for operating a sputtering source, according to embodiments described herein.

### DETAILED DESCRIPTION OF EMBODIMENTS

Reference will now be made in detail to the various embodiments of the present disclosure, one or more examples of which are illustrated in the figures. Within the following description of the drawings, the same reference numbers refer to the same components. Generally, only the differences with respect to individual embodiments are described. Each example is provided by way of explanation of embodiments of the disclosure and is not meant as a limitation of the embodiments. Further, features illustrated or described as part of one embodiment can be used on or in conjunction with other embodiments to yield yet a further embodiment. It is intended that the description includes such modifications and variations.

A sputtering source as described herein refers to an assembly including a backing support and a magnet assembly. A target material to be sputtered might be applied to the backing support. The backing support can be a plate, cylinder, tube or other structure. The term “sputtering source” as used herein refers to any electrode assembly which is adapted to be mounted to a sputter deposition apparatus and which might include a target material for being sputtered. The term “target” as used herein refers to a target material or target tile comprising a material to be deposited on a substrate.

For planar sputtering sources, the surface of the backing structure and the surface of the target material may be flat, particularly in one dimension. That is, the target material and the backing structure may have a constant thickness along the length of the backing structure, particularly in one dimension. For example, the target may be a planar target. Yet further, the planar target may have a dog-bone structure, i.e. the target thickness can be increased in an area of the magnetron, where the racetrack turns around.

According to embodiments described herein, a thermal conduction interface similar to a solid state interface can be provided between a target and a backing support, i.e. support for supporting the target. The thermal conduction interface might be provided by using perpendicular contact surfaces in relation to a thermal expansion direction.

The physics behind this thermal conduction is that the crucible, e.g., a target or a target tile, may expand in case of heating. In this case, a thermal expansion of the target may be caused by the existing plasma. Based on this thermal expansion a thermal interface between the target material and backing support might be created. The hotter the target becomes, the more pressure may be realized on the backing support. With a high pressure, the thermal conduction may be close to that of a solid material. In case of not optimized contact between the target material and the backing support, the target material may become hotter and may have more thermal expansion. As explained above, the target may accordingly create a better thermal conduction with the backing support. As a result, the target material has a better cooling.

Embodiments described herein relate to a heat sensitive material, e.g., alkali metal or alkaline earth metal, when used as a target material for a sputtering process. In particular, embodiments described herein relate to lithium when used as a target material for a sputtering process. Some properties of lithium, e.g., sensitivity to moisture and/or air exposure, being relatively soft and malleable, and having a relatively low melting point, make it a challenging material for the fabrication of lithium sputter targets and their use in sputtering processes. For example, exposure to ambient air oxidizing vapours, in particular H2O, and contact with personnel after opening the vacuum chamber should be minimized.

Compared to other alkali metals, lithium is of particular interest since it is suitable for the production of high energy density batteries and accumulators. For instance, these batteries might be interesting for industrial transport vehicles or for batteries in laptops, phones and other electronic devices.

In cases where the target is made of a heat sensitive material, the material may melt and/or may have poor adhesion to the backing plate when the heat load received by the target during the sputtering process is not properly dissipated. The term “heat sensitive material” as used herein refers to materials with a low melting point, i.e., between 25 and 650° C. Particularly, heat sensitive materials might be selected from the group consisting of an alkali metal or alkaline earth metal. More particularly, a heat sensitive target material might be lithium.

Embodiments described herein further relate to other metal and metal alloy sputtering targets, e.g., high purity aluminum alloy, copper, titanium, molybdenum sputtering targets, may also be used.

For some target materials, in particular heat sensitive materials, cooling of the target material and bonding of the target material to the backing support might be more difficult than with other materials. In view of the foregoing, one measure for cooling might be to use the above described physical process to improve the thermal conduction of a target to the backing support. This is a self-stabilization system. The cool target, i.e., without additional cooling, will be cooled by the bonding contact with the backing support only. The hotter the target becomes, the more pressure may be created on the backing support by the thermal expansion of the target. Accordingly, the target creates better thermal conduction with the backing support. As a result, the target material has a better cooling.

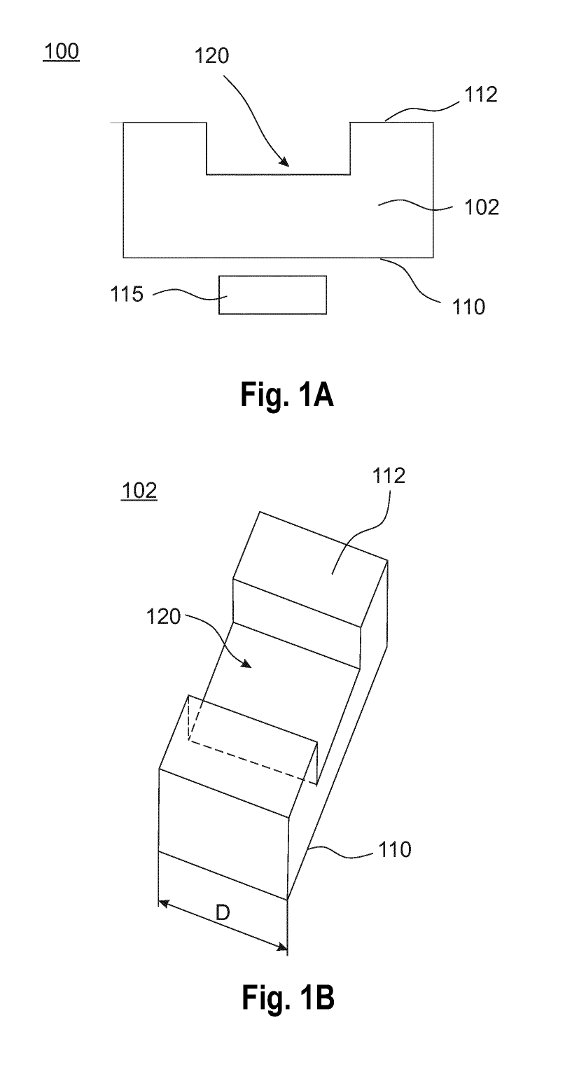

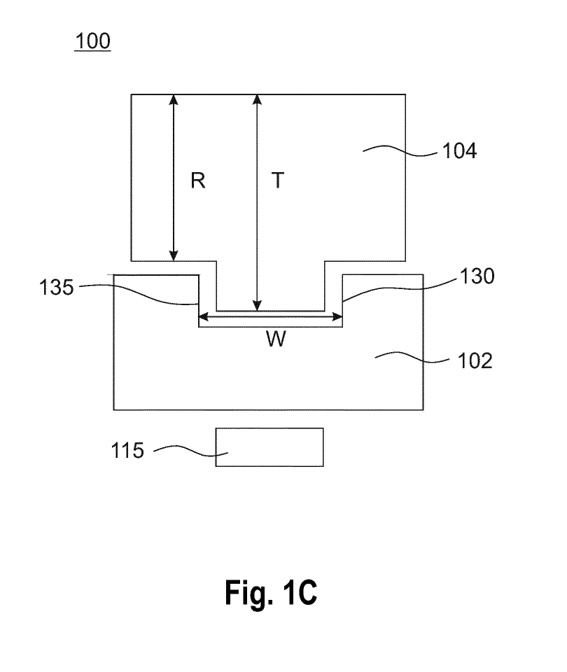

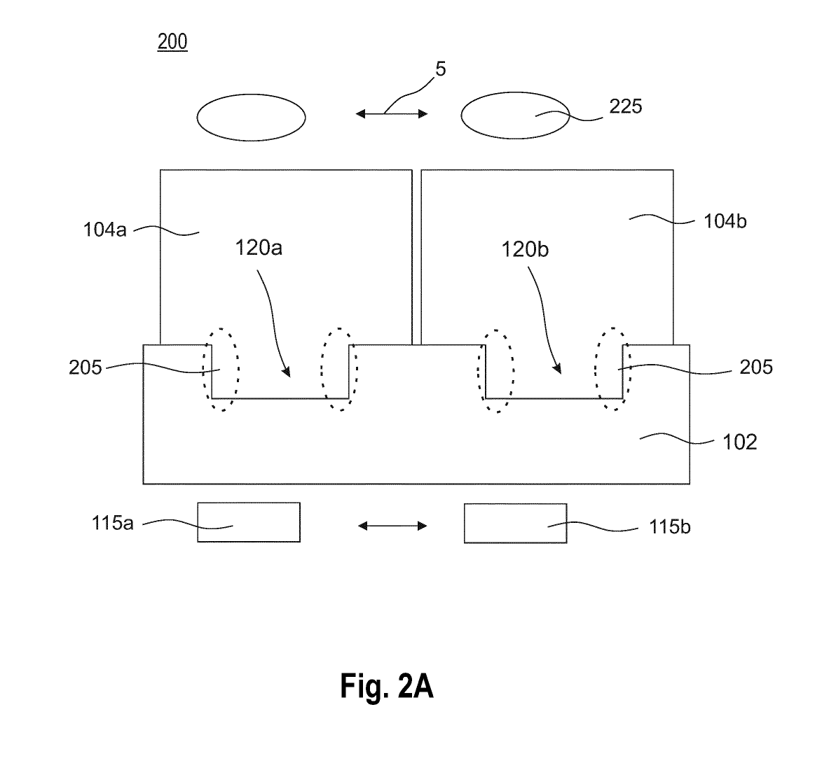

FIG. 1A shows a cut view of a sputtering source 100. According to embodiments of the present disclosure, the sputtering source may have a backing support 102. The backing support may have a target receiving surface 112 and a further surface 110 opposing the target receiving surface. The sputtering source may further comprise at least one magnet assembly 115 provided adjacent the further surface 110. As shown in FIG. 1A, the target receiving surface 112 of the backing support may have at least one recess 120. The recess may be provided opposite to the magnet assembly. Accordingly, the sputtering source may have a better thermal conduction between the target material and the backing support due to a thermal interface created at the recess. As a result, the target material can be cooled in an optimized way.

According to different embodiments, which can be combined with other embodiments described herein, the backing support 102 may be made of a material selected from the group consisting of: a metal, e.g., copper or titanium, an alloy, e.g, stainless steel, and any combination thereof. In particular, copper may be used because it has a good thermal conductivity (400 W/m·K).

As described above, the sputtering source may comprise a magnet assembly 115 in order to obtain increased deposition rates. According to embodiments herein, the magnet assembly may be arranged at the height of the recess and may provide a magnetic field for magnetically enhanced sputtering. According to further embodiments, the magnet assembly may be attached to the backing support at the further surface.

FIG. 1B shows a perspective view of the backing support 102 of FIG. 1A. The target receiving surface 112 of the backing support may have at least one recess 120. As can be seen in FIG. 1B, the recess of the backing support may have a rectangular shape and may extend along the depth D of the backing support. A magnet assembly (not shown) may be provided adjacent the further surface 110. The recess may be provided opposite to the magnet assembly.

According to embodiments of the present disclosure, the sputtering source may comprise a target material to be sputtered. Referring to FIG. 1C, a top view of the sputtering source 100 of FIG. 1A comprising a target material 104 is shown. The target receiving surface 112 may be configured to hold the target material 104. The target receiving surface may be facing the target material and may be in the same direction as the substrate is to be placed. The further surface 110 may be opposite to the target receiving surface. The further surface may be facing the magnet assembly 115 and may be in the opposite direction to that in which the substrate is to be placed.

According to further embodiments which can be combined with other embodiments described herein, the sputtering source may be a planar sputtering source and the backing support may be a backing plate.

As can be seen in FIG. 1C, the thickness of the target material at a region opposite to the recess of the backing support T is higher than the thickness of the target material at a region away from the recess of the backing support R. The region opposite to the recess of the backing support may be a region with higher plasma activity since this region is in front of the magnet assembly. Accordingly, the erosion of the target material can be deeper based on this additional thickness. As a result, there is a better utilization of the target material.

In addition, the backing support surface might have a recess and the target bonding surface might have a protrusion, such that the target might have a larger thickness in the area of plasma activity. Accordingly, the erosion of the target material can be greater based on this additional thickness. As a result, there is a better utilization of the target material.

Furthermore, the presence of a recess at the backing support provides a sputtering source with a thermal interface between the target material and the backing support. Accordingly, the sputtering source may have a better thermal conduction between the target material and the backing support. As a result, the target material can be cooled in an optimized way.

According to further embodiments, which can be combined with other embodiments described herein, the thickness of the target material at a region corresponding to the recess of the backing support may be in the range of 2 to 40 mm, particularly, the thickness of the target material at a region corresponding to the recess or opposite to the recess of the backing support may be in the range of 5 to 30 mm, more particularly, the thickness of the target material at a region corresponding to the recess or opposite to the recess of the backing support may be in the range of 5 to 20 mm.

According to yet further embodiments, the difference between the thickness of the target material at a region opposite to the recess of the backing support T and at a region away from the recess of the backing support R may be of 1 mm or more, particularly, the difference may be of 3 mm or more, more particularly, the difference may be of 5 mm or more.

According to further embodiments, the target material may have a protrusion configured to engage the recess of the backing support. The target material may not be pressed into a recess of the backing support but may be provided on the target receiving surface 112 of the backing support. For providing the target material on the target receiving surface, the size of the protrusion may be slightly smaller, for example, 0.25 mm to 0.6 mm smaller), than the recess in the backing support. By having a smaller protrusion size, the target material can be mounted to the backing support more easily, for example without frictional problems.

As can be seen in FIG. 1C, the protrusion of the target material and the recess of the backing support may have a rectangular shape. According to present embodiments, before the sputtering process starts, the size of the protrusion might be smaller than the recess in the backing support. By having a smaller protrusion size, the target material can be mounted to the backing support more easily. During the sputtering process, high powered ions are accelerated towards the target material and the target material experiences a high heat load. The heat load may cause a thermal expansion of the target. Based on this thermal expansion, the protrusion of the target material may fit completely in the recess of the backing support, for example the protrusion is pressed into the recess of the backing support. As a result, a thermal interface between the target material and the recess of the backing support might be created or improved. At this thermal interface, thermal conduction between the target material and the backing plate may take place. The higher the pressure is at the recess, the better the thermal conduction may be.

In view of the foregoing, a sputtering source as described herein may have a better thermal conduction between the target material and the backing support. As a result, the target material can be cooled in an improved way. As mentioned above, the target material might be cooled in order to avoid melting and/or evaporation of the target material, especially when the target is made of a heat sensitive material. Furthermore, the presence of a recess at the backing support provides a target with a larger thickness in the area of plasma activity. Accordingly, the erosion of the target material can be deeper based on this additional thickness. As a result, there is a better utilization of the target material.

According to embodiments of the present disclosure, the recess 120 may have a width W. The width may be parallel to the lower surface of the protrusion of the target material. The width W of the recess may be large enough to allow the target material to be mounted to the backing support without frictional problems. The width W of the recess may be also large enough to allow for a deep erosion groove of the target material at the region opposite to the recess of the backing support. A deep erosion groove provides a better utilization of the target material. According to particular embodiments of the present disclosure, the width of the recess may be at least 100% of the width of the magnet assembly, particularly, the width of the recess may be at least 150% of the width of the magnet assembly, more particularly, the width of the recess may be at least 200% of the width of the magnet assembly.

According to yet further embodiments, the recess may have a first surface 130 opposing a second surface 135. The first surface of the recess may be parallel to the second surface of the recess. More particularly, the first surface may have an inclination of between 0° to 10° with respect to the second surface. A recess with a rectangular or essentially rectangular structure provides a better thermal interface between the target material and the backing support. Accordingly, the target creates a better thermal conduction with the backing support. As a result, the target material has a better cooling.

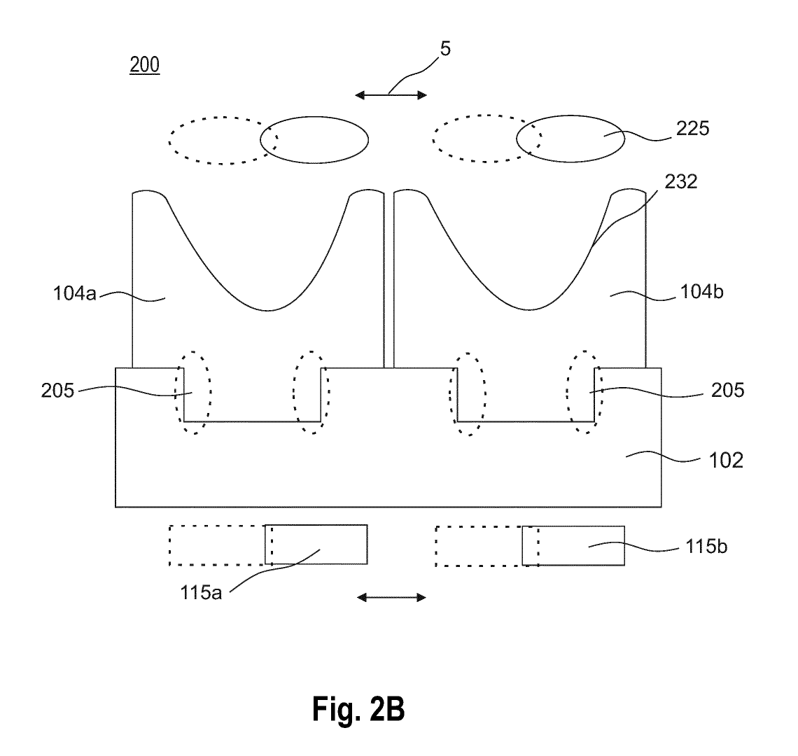

A top view of a sputtering source comprising multiple target tiles is shown in FIG. 2A. As used herein the term “target tiles” refers to tiles of target material to be sputtered. According to embodiments of the present disclosure, the sputtering source may have a backing support. The backing support may have a target receiving surface and a further surface opposing the target receiving surface. The backing support may be configured to receive one or more target tiles at the target receiving surface.

As shown in FIG. 2A, the sputtering source 200 may have two target tiles 104a, 104b provided on the backing support 102. The sputtering source may further comprise two magnet assemblies 115a, 115b. According to embodiments of the present disclosure, the backing support may have two recesses 120a, 120b. The recesses may be provided opposite to the magnet assemblies 115a, 115b. According to particular embodiments, the recess 120a may be provided opposite to the magnet assembly 115a and the recess 120b may be provided opposite to the magnet assembly 115b.

According to embodiments herein, the sputtering source of FIG. 2A may be a planar sputtering source and the backing support may be a backing plate. As mentioned above, planar sputtering sources might also be used for large area substrate processing. In that case, multiple tiles of sputtering material might be separately bonded to a single backing plate. According to embodiments herein, the sputtering source may comprise a single backing plate, i.e., a one-piece backing plate structure, which gives support for the one or more target tiles.

As outlined above, during the sputtering process charged ions from the plasma may impact on the surface of the target material. These impacts may make the target material become even more hot. Due to the heat, the target material may thermally expand such that the protrusion may contact the recess of the backing support creating a thermal interface between the target material and the backing support. Based on this thermal expansion, the protrusion of the target material may fit completely into the recess of the backing support and/or is pressed into the recess of the backing support. A thermal interface between the target material and the recess of the backing support might be created. At this thermal interface, thermal conduction between the target material and the backing plate may take place. The higher the pressure is on the recess, the better the thermal conduction may be.

Accordingly, a sputtering source as described herein may have a better thermal conduction between the target material and the backing support due to the thermal interface created at the recess. As a result, the target material can be cooled in an optimized way. As mentioned above, the target material might be cooled in order to avoid melting and/or evaporation of the target material, especially when the target is made of a heat sensitive material.

According to further embodiments which can be combined with other embodiments herein, during the sputtering process, the target tile 104a may thermally expand such that the protrusion of the target tile may contact the recess 120a of the backing support creating two thermal interfaces 205 between the target material and the backing support. Likewise, during the sputtering process, the target tile 104b may thermally expand such that the protrusion of the target tile may contact the recess 120b of the backing support creating two thermal interfaces 205 between the target material and the backing support.

According to alternative embodiments, the sputtering source may comprise multiple backing plates. Accordingly, each backing plate may provide support for one target tile. The multiple backing plates may be fastened to each other by attachment means. The attachment means can be selected from the group consisting of: a clamp, a screw, a solder, and combinations thereof.

FIG. 2B shows a top view of a sputtering source comprising multiple target tiles. Particularly, the sputtering source of FIG. 2B shows the sputtering source of FIG. 2A after a first sputtering cycle. According to embodiments of the present disclosure, the sputtering source 200 may have a backing support 102. The backing support may have a target receiving surface and a further surface opposing the target receiving surface. The sputtering source 200 may have two target tiles 104a, 104b provided on the backing support 102. The sputtering source may further comprise two magnet assemblies 115a, 115b. According to embodiments of the present disclosure, the backing support may have two recesses 120a, 120b. The recesses may be provided opposite to the magnet assemblies 115a, 115b. According to particular embodiments, the recess 120a may be provided opposite to the magnet assembly 115a and the recess 120b may be provided opposite to the magnet assembly 115b.

According to further embodiments of the present disclosure, the sputtering process may be a magnetron sputtering process using AC and/or DC current. The sputtering process may be conducted in a gaseous atmosphere. Current may be applied to the sputtering source to generate a plasma in the vicinity of the target material, i.e., a mixture of ionized gas atoms and free electrons. As shown in FIG. 2B, the magnetic field provided by the magnet assemblies 115a, 115b may enhance the formation of plasma areas 225 in the vicinity of the target tiles 104a, 104b. Accordingly, the gas in the deposition chamber, remote from the area of plasma confinement due to the magnets (magnetron sputtering), may remain largely unionized. During the sputtering process charged ions from the plasma may be accelerated towards the target material and impact upon its surface dislodging atoms of the target material. The dislodged atoms may be deposited on a substrate (not shown).

As can be seen from FIG. 2B, the intensity of the plasma, and the rate of sputtering, may be higher in a region close to the magnet assembly than in a region further away from the magnet assembly. Accordingly, the target material may be sputtered principally from the region opposite to the recess of the backing support. The region opposite to the recess of the backing support is also opposite to the magnet assembly. As outlined above, the target may have a larger thickness in the area close to the magnet assembly. Based on this larger thickness, the erosion of the target material can be deeper at the region opposite to the recess of the backing support. As a result, there is a better utilization of the target material. The atoms dislodged from the target may create an erosion groove 232 in the target tiles. The erosion groove can be deeper at the region opposite to the recess of the backing support.

According to further embodiments which can be combined with other embodiments described herein, the magnetic field provided by the magnet assembly 115a may enhance the formation of a plasma area 225 in the vicinity of the target tile 104a. Likewise, the magnetic field provided by the magnet assembly 115b may enhance the formation of a plasma area 225 in the vicinity of the target tile 104b. The target tiles 104a, 104b may have a larger thickness in the area close to the magnet assemblies 115a, 115b. Based on this larger thickness, the erosion of the target material can be deeper at the regions opposite to the recesses of the backing support. The atoms dislodged from the target tiles 104a, 104b may create an erosion groove 232 in the surface of the target tiles.

According to embodiments herein, the magnet assembly may be a movable magnet assembly. By moving the magnet assembly, the plasma area may also move in the same direction under the influence of the magnetic field. According to further embodiments, the magnet assembly 115 may be moved in the direction of arrow 5, i.e., a direction parallel to the further surface of the backing support, such that the plasma area 225 may move in the same direction. By moving the plasma area with respect to the surface of the target material, the area where sputtering takes place may be controlled. Accordingly, sputtering can take place along a wider surface of the target material and the erosion of the target material is more homogeneous along the direction parallel to the further surface of the backing support. As a result, there is a better utilization of the target material. The dotted lines in FIG. 2B show the movement of plasma areas 225 in response to the movement of magnet assemblies 115a, 115b.

According to further embodiments, the magnet assembly may be a fixed magnet assembly, i.e., a magnet assembly which cannot be moved during the sputtering process.

According to embodiments of the present disclosure, the sputtering source may comprise attachment means (not shown) to hold the target material at the backing support. This attachment means may be used alternatively or in addition to a bonding between the target material and the backing support. As a result of the thermal expansion of the target material the target is pressed into the backing support. Accordingly, the attachment means may function for holding the target to the backing support when the target is at room temperature or not at high temperatures (without thermal expansion). For example, the attachment means can hold the target to the backing support during maintenance or the like. Upon heating of the target, i.e. when the target is pressed into the backing support by thermal expansion, the attachment means may still be present but does not significantly contribute to attaching the target to the backing support. Accordingly, the attachment means can be configured to attach the target to the backing support in an unheated state. According to further embodiments, the attachment means may be selected from the group consisting of: a clamp, a screw, solder and any combination thereof.

According to embodiments herein, the target material may be a high purity metal or metal alloy. According to further embodiments, the target material may be an alkali metal or alkaline earth metal. Particularly, the target material may be lithium. According to yet further embodiments, high purity aluminum alloy sputtering targets can be used in semiconductor manufacturing. Likewise, other metal and metal alloy sputtering targets, e.g., from copper, titanium, molybdenum sputtering targets, may be used.

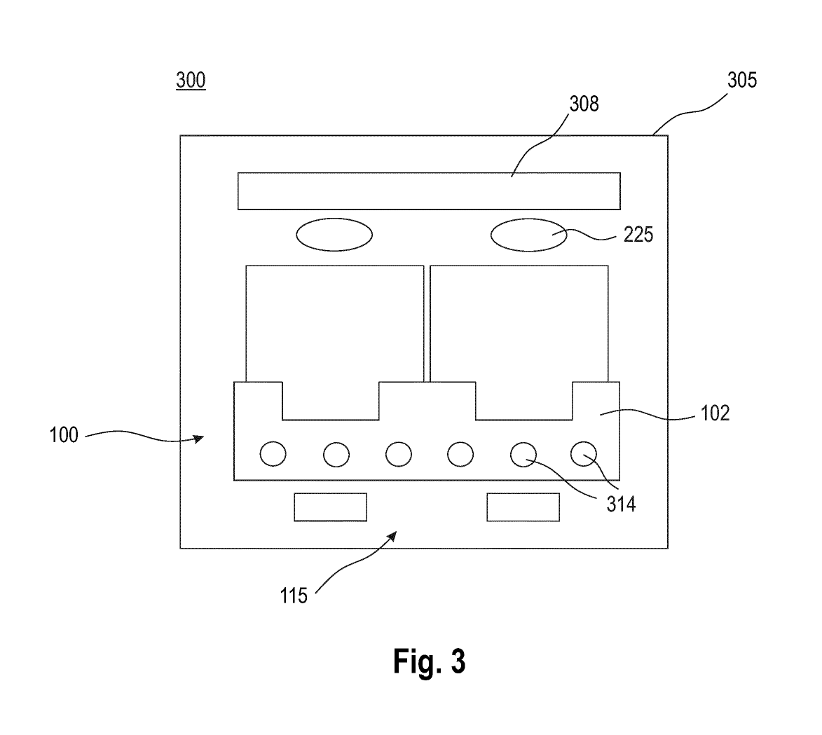

FIG. 3 shows a schematic view of an apparatus 300 for sputter deposition of a substrate 308. The apparatus may comprise a vacuum chamber 305 configured for sputter deposition of a substrate and a sputtering source 100. The sputtering source 100 corresponds to the sputtering source of any of FIGS. 2A and 2B. The sputtering source may have a backing support 102. The backing support may have a target receiving surface and a further surface opposing the target receiving surface. The sputtering source may further comprise at least one magnet assembly 115 provided adjacent the further surface. The target receiving surface of the backing support may have at least one recess. The recess may be provided opposite to the magnet assembly. The target receiving surface may be configured to hold a target material. Accordingly, the target receiving surface may be facing the target material and may be in the direction where the substrate 308 is placed. The further surface may be opposite to the target receiving surface. Accordingly, the further surface may be facing the magnet assembly and may be in the direction opposite to where the substrate 308 is placed.

As shown in FIG. 3, the magnetic field provided by the magnet assemblies 115 may enhance the formation of plasma areas 225 in the vicinity of the target tiles 104a, 104b. Accordingly, the gas in the chamber 305, remote from the target material, may remain largely unionized. During the sputtering process, charged ions from the plasma may be accelerated towards the target material and impact upon its surface dislodging atoms of the target material. The dislodged atoms may be deposited on the substrate 308.

According to further embodiments, the sputtering source 100 may be a source appropriate to be connected to an AC power supply or a DC power supply (not shown).

According to embodiments herein, the apparatus 300 may comprise cooling means 314 for cooling the backing support. For instance, cooling channels with a cooling liquid may be used to cool the backing support.

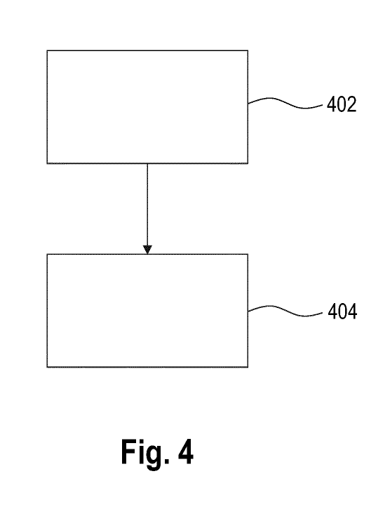

An embodiment of a method for operating a sputtering source is shown as a schematic drawing in FIG. 4. The method may include providing a magnet assembly 402. The method may further include providing a backing support having a target receiving surface and a further surface opposing the target receiving surface, wherein the target receiving surface of the backing support has at least one recess, wherein the recess is provided opposite to the magnet assembly 404. Accordingly, the sputtering source may have a better thermal conduction between the target material and the backing support due to a thermal interface created at the recess. As a result, the target material can be cooled in an optimized way. Furthermore, the presence of a recess at the backing support provides a target with a larger thickness in the area of plasma activity. Accordingly, the erosion of the target material can be greater based on this additional thickness. As a result, there is a better utilization of the target material.

The embodiments described herein can be utilized for deposition on large area substrates, for example, architectural scale windows having, e.g., electrochromic devices thereon including lithium, or lithium battery manufacturing. According to different embodiments, which can be combined with other embodiments described herein, the embodiments described herein can be utilized for Display PVD, i.e. sputter deposition on large area substrates for the display market.

According to some embodiments, large area substrates or respective carriers, wherein the carriers have one or more substrates, may have a size of at least 0.67 m². The size can be about 0.67 m² (0.73×0.92 m−Gen 4.5) to about 8 m², more typically about 2 m² to about 9 m² or even up to 12 m². The substrates or carriers, for which the structures, apparatuses, such as cathode assemblies, and methods according to embodiments described herein are provided, are large area substrates as described herein. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

While the foregoing is directed to embodiments of the present disclosure, other and further embodiments may be devised without departing from the basic scope thereof, and the scope thereof is determined by the claims that follow.

1. A sputtering source comprising:
a backing support having a target receiving surface configured to face the target material and having and a further surface opposing the target receiving surface; and
at least one magnet assembly provided adjacent the further surface, wherein the target receiving surface of the backing support has at least one recess, wherein the recess is provided opposite to the magnet assembly.

2. The sputtering source of claim 1, comprising a target material, wherein a thickness of the target material at a region opposite to the recess of the backing support is higher than a thickness of the target material at a region away from the recess of the backing support.

3. The sputtering source of claim 2, wherein a difference between the thickness of the target material at a region opposite to the recess of the backing support and the thickness of the target material at a region away from the recess of the backing support is 1 mm or more.

4. The sputtering source of claim 1, wherein a width of the recess is at least 100% of a width of the magnet assembly.

5. The sputtering source of claim 1, wherein the recess has a first surface opposing a second surface, wherein the first surface has an inclination of between 0° to 10° with respect to the second surface.

6. The sputtering source of claim 2, comprising attachment means to hold the target material at the backing support.

7. The sputtering source of claim 6, wherein the attachment means may be selected from the group consisting of: a clamp, a screw, a solder and any combination thereof.

8. The sputtering source of any of claim 2, wherein the target material is selected from the group consisting of an alkali metal and an alkaline earth metal.

9. A method for operating a sputtering source comprising:
providing a magnet assembly; and
providing a backing support having a target receiving surface configured to face the target material and having a further surface opposing the target receiving surface, wherein the target receiving surface of the backing support has at least one recess, wherein the recess is provided opposite to the magnet assembly.

10. The method of claim 9, comprising providing a target material on the target receiving surface of the backing support, wherein the target material comprises a protrusion configured to engage the recess of the backing support.

11. The method of claim 10, wherein the target material thermally expands such that the protrusion contacts the recess of the backing support creating a thermal interface between the target material and the backing support.

12. The method of claim 11, comprising cooling the target material by thermal conduction at the thermal interface between the target material and the backing support.

13. The method of claim 9, comprising moving the magnet assembly in a direction parallel to the further surface of the backing support, such that a plasma area moves in the same direction as the magnet assembly.

14. An apparatus for sputter deposition of a substrate, comprising:
a vacuum chamber configured for sputter deposition of a substrate; and
a sputtering source comprising:
a backing support having a target receiving surface configured to face the target material and having and a further surface opposing the target receiving surface; and
at least one magnet assembly provided adjacent the further surface, wherein the target receiving surface of the backing support has at least one recess, wherein the recess is provided opposite to the magnet assembly.

15. The apparatus of claim 14, comprising cooling means for cooling the backing support.

16. The method of claim 10, wherein a width of the recess is at least 100% of a width of the magnet assembly.

17. The apparatus of claim 15, comprising a target material, wherein a thickness of the target material at a region opposite to the recess of the backing support is higher than a thickness of the target material at a region away from the recess of the backing support.

18. The apparatus of claim 15, wherein a difference between the thickness of the target material at a region opposite to the recess of the backing support and the thickness of the target material at a region away from the recess of the backing support is 1 mm or more.

19. The apparatus of claim 15, wherein a width of the recess is at least 100% of a width of the magnet assembly.

20. The apparatus of claim 15, wherein the recess has a first surface opposing a second surface, wherein the first surface has an inclination of between 0° to 10° with respect to the second surface.
